(19) United States
(12) Patent Application Publication
(10) Pub. No.: US 2004/0018646 A1
(43) Pub. Date: Jan. 29, 2004

(54) Resist pattern formation method

(75) Inventors: Shinji Tarutani, Hyogo (JP); Toshiyuki Toyoshima, Hyogo (JP); Takeo Ishibashi, Hyogo (JP); Yuuko Odamura, Hyogo (JP); Naoki Yasuda, Hyogo (JP)

Correspondence Address: LEYDIG VOIT & MAYER, LTD, 700 THIRTEENTH ST. NW, SUITE 300, WASHINGTON, DC, 20005-3960, US

(73) Assignees: Mitsubishi Denki Kabushiki Kaisha, Tokyo (JP); Ryoden Semiconductor System Engineering Corporation, Itami-shi (JP)

(21) Appl. No.: 10/334,992

(22) Filed: Jan. 2, 2003

(30) Foreign Application Priority Data
Jul. 23, 2002 (JP) 2002-214164

(51) Int. Cl. H01L 21/00; H01L 21/66; G01R 31/26

(52) U.S. Cl. 438/4; 438/7

(57) ABSTRACT

A resist pattern formation method is characterized in that, after a resist pattern is formed on a wafer, a residue generated between resist sidewalls forming the resist pattern is irradiated with an electron beam under a reduced pressure. It is also preferable to detect the residue with pattern defect inspection equipment, and irradiate the detected residue site with an electron beam under a reduced pressure using an electron microscope. The reduced pressure is preferably equal to or lower than 5.0×10² Pa, and an acceleration voltage is preferably equal to or lower than 1200 V. A manufacturing method of a semiconductor device according to the present invention uses the above-described formation method to form a resist pattern. Thus, the residue generated between resist sidewalls can be removed without varying a dimension of a resist pattern spacing.

### BACKGROUND OF THE INVENTION

1. Field of the Invention

The present invention relates to a resist pattern formation method, which is included in lithography technology in semiconductor manufacturing process, and a manufacturing method of a semiconductor device using the formation method. More specifically, the present invention relates to a resist pattern formation method wherein a residue generated between resist sidewalls forming the resist pattern can be removed without varying a resist pattern spacing, and to a manufacturing method of a semiconductor device using the formation method.

2. Description of the Background Art

To enhance high integration of a semiconductor device, technology for finer resist pattern has rapidly advanced with lithography technology wherein a circuit pattern is formed on a wafer as a resist image. As a spacing of the resist pattern becomes smaller with this technology, in a sequential resist pattern formation process including resist application, exposure, development, rinsing, and drying steps, a residual resist swelled during the development step may contact with a resist sidewall, and may generate a residue, for example, of a string-like, band-like or grid-like shape (which will simply be referred to as “residue” hereinafter), which links resist sidewalls after the rinsing and drying steps.

Particularly, the residue can easily be generated in a situation such as when a resist material easily swells in particular developer, or when a spacing of formed resist pattern is as small as 0.20 μm or smaller.

If the residue remains, it may cause defective opening, short-circuit, disconnection and the like, and extremely decreases the yield of the semiconductor device.

Choosing of a combination of a resist material and developer so as not to generate the residue has disadvantages such that it limits the material, and a desired semiconductor device may not be manufactured. In addition, as the resist pattern spacing becomes smaller, generation of the residue cannot be avoided only with the combination of a resist material and developer. On the other hand, when a heat curing process or a DUV (Deep Ultra Violet) curing process is used to remove the generated residue, dimension of the resist pattern varies, which is adverse to the demand for a finer resist pattern.

### SUMMARY OF THE INVENTION

An object of the present invention is to provide a resist pattern formation method wherein the residue is removed without varying a dimension of a resist pattern spacing.

To attain the above-described object, a resist pattern formation method according to one aspect of the present invention is characterized in that, after a resist pattern is formed on a wafer, a residue generated between resist sidewalls forming the resist pattern is removed without varying a dimension of a resist pattern spacing by irradiating the residue with an electron beam under a reduced pressure.

Furthermore, a resist pattern formation method according to another aspect of the present invention is characterized in that, after a resist pattern is formed on a wafer, a residue generated between resist sidewalls forming the resist pattern is detected using pattern defect inspection equipment, and is removed without varying a dimension of a resist pattern spacing by irradiating the detected residue site with an electron beam under a reduced pressure.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view of a mask used for forming a resist pattern in one embodiment of the present invention.

FIG. 2A is a schematic view of a first resist pattern formation process in one embodiment of the present invention. FIG. 2B schematically shows generation of a residue during formation of a second resist pattern in one embodiment of the present invention. FIG. 2C schematically shows removal of the residue in one embodiment of the present invention.

FIG. 3A is a microphotograph of a part of a resist pattern before an electron beam irradiation step in one embodiment of the present invention. FIG. 3B is a microphotograph of a part of the resist pattern after the electron beam irradiation step in one embodiment of the present invention.

FIG. 4 is a schematic view of a mask used for forming a resist pattern in another embodiment of the present invention.

FIG. 5A is a schematic view of a first resist pattern formation process in another embodiment of the present invention. FIG. 5B schematically shows generation of a residue during formation of a second resist pattern in another embodiment of the present invention. FIG. 5C schematically shows removal of the residue in another embodiment of the present invention.

FIGS. 6A to 6J are general cross-sections of a resist pattern spacing reduction process, which is one form of a resist pattern formation method to which the present invention is applied.

FIG. 7A schematically shows a dissolving step of non-cross-linked second resist in the resist pattern spacing reduction process. FIG. 7B schematically shows a swelling step of a second resist cross-linked layer in the resist pattern spacing reduction process. FIG. 7C schematically shows generation of a residue in the resist pattern spacing reduction process.

### DESCRIPTION OF THE PREFERRED EMBODIMENTS

A resist pattern formation method according to the present invention is to remove a residue generated between resist sidewalls forming the resist pattern without varying a dimension of a resist pattern spacing by irradiating the residue with an electron beam under a reduced pressure after the resist pattern is formed on a wafer.

In the present invention, the term “without varying a dimension of a resist pattern spacing” means that the variation of the dimension by the electron beam irradiation is equal to or smaller than 5 nm. This is because, formation of a finer resist pattern becomes difficult when a larger variation in dimension occurs.

Though a method and an apparatus for electron beam irradiation are not limited to particular ones, it is preferable to include an electron irradiation tube that can obtain an acceleration voltage equal to or lower than 1200 V. This is because, the variation in resist pattern spacing is difficult to be kept equal to or smaller than 5 nm with the acceleration voltage higher than 1200 V. The acceleration voltage is more preferably equal to or lower than 1000 V, and further preferably equal to or lower than 800 V. An apparatus for electron beam irradiation particularly includes a low acceleration voltage and wide range electron beam irradiation unit, an electron microscope and the like. The low acceleration voltage and wide range electron beam irradiation unit has the advantage in its capability to irradiate a wide range with an electron beam at a time, while the electron microscope is advantageous when it is desirable to irradiate only a residue portion with an electron beam while observing the portion, because an electron beam irradiation range at a time is smaller with the electron microscope.

The residue can be removed without varying the dimension when the irradiation time of the electron beam is equal to or shorter than 30 seconds. In addition, the irradiation time can be set to be equal to or longer than 8 seconds when the acceleration voltage is from 300 V to lower than 500 V, equal to or longer than 5 seconds when the acceleration voltage is from 500 V to lower than 800 V, and equal to or longer than 2 seconds when the acceleration voltage is from 800 V to 1200 V, to decrease the irradiation time without leaving the residue.

Though the state of reduced pressure is not limited to a particular state as long as the electron beam irradiation is possible in the acceleration voltage lower than the above-mentioned value, the pressure is preferably equal to or lower than 5.0×102 Pa. With this point in view, it is desirable that the apparatus for electron beam irradiation is provided with a chamber which can attain a reduced pressure equal to or lower than 5.0×102 Pa.

It is preferable that, in a resist pattern formation method according to the present invention, after a resist pattern is formed on a wafer, a residue generated between resist sidewalls forming the resist pattern is detected using pattern defect inspection equipment, and is removed without varying a dimension of a resist pattern spacing by irradiating the detected residue site with an electron beam under a reduced pressure.

Though the pattern defect inspection equipment is not limited to particular one as long as it can identify and detect the pattern defective site, it is generally preferable to use equipment which can optically or electronically identify and detect the defective site of the object by contrasting with a complete site to digitize and display the result. For rapid detection of a residue-generated site, it is desirable to concurrently use the pattern defect inspection equipment when an electron microscope is used as an electron beam irradiation apparatus, because an electron beam irradiation range at a time is small with the electron microscope, as described above.

In addition, the use of the pattern defect inspection equipment for detecting a residue in combination with the electron microscope for irradiating the detected residue with an electron beam is preferable not only for the rapid detection of the residue-generated site, but also for irradiating only the detected residue site with the electron beam.

Though the resist pattern formation method according to the present invention is widely applicable to form a resist pattern, the method is more advantageous for a resist pattern with a smaller spacing. The method is especially effective when applied to a resist pattern spacing reduction process utilizing a chemical reaction, which process was developed by the applicant of the present invention. The application to the resist pattern spacing reduction process will mainly be described hereafter.

The above-described process developed by this applicant is a process to reduce a first resist pattern spacing by forming the first resist pattern with a normal exposure step, forming an upper layer film by applying water-soluble upper layer agent for formation of a second resist pattern, and diffusing acid in the first resist into the upper layer film by heating to form a new cured layer on an inner wall of a sidewall of the first resist (disclosed, for example, in Japanese Patent Laying-Open No. 10-73927).

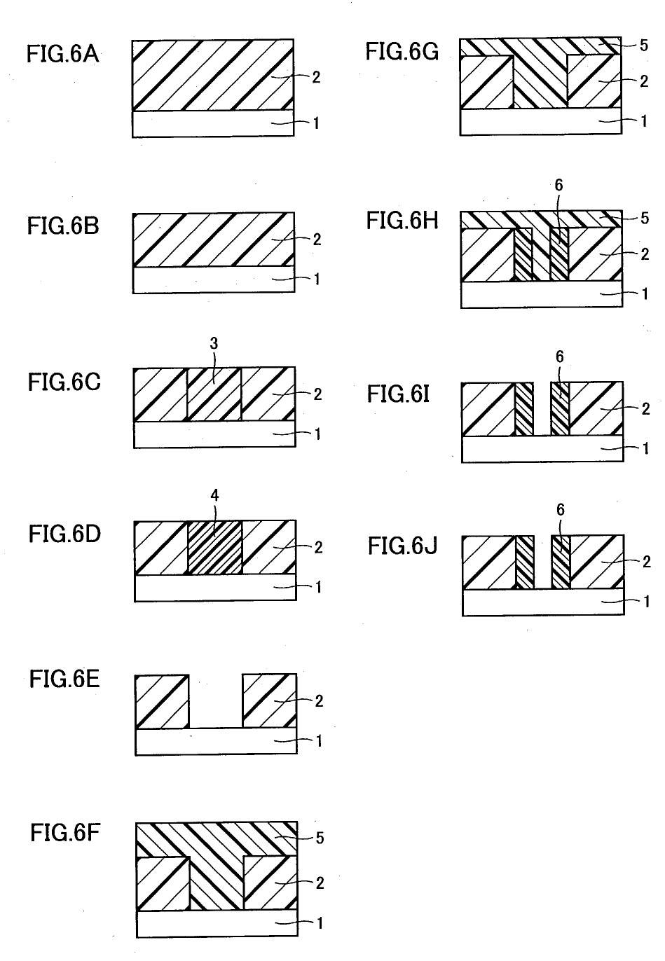

A general process of the aforementioned resist pattern spacing reduction process will now be described with reference to FIGS. 6A-6J. First, a chemically amplified excimer resist as a first resist 2 is applied on a silicon wafer 1 in a step shown in FIG. 6A, and solvent in the resist is dried by pre-baking in a step shown in FIG. 6B. An altered portion 3 is provided in the first resist by an exposure step using a prescribed mask as shown in FIG. 6C, and then altered portion 3 is further turned to an altered portion 4 by a post-exposure bake (PEB) step shown in FIG. 6D. A first resist pattern is obtained by removing altered portion 4 by alkaline development in a step shown in FIG. 6E. Thereafter, in a step shown in FIG. 6F, the aforementioned water-soluble upper layer agent as a second resist 5 for the pattern spacing reduction process is applied on the silicon wafer with the first resist pattern formed thereon, and a second resist film is formed by a pre-bake step shown in FIG. 6G. Mixing-bake is then performed in a step shown in FIG. 6H to form a second resist cross-linked layer 6 in the second resist film with acid supplied from the first resist. Pure water development is performed in a step shown in FIG. 6I to remove non-cross-linked second resist 5, and then post-bake is performed in a step shown in FIG. 6J to form second resist cross-linked layer 6 on the first resist pattern to reduce the resist pattern spacing.

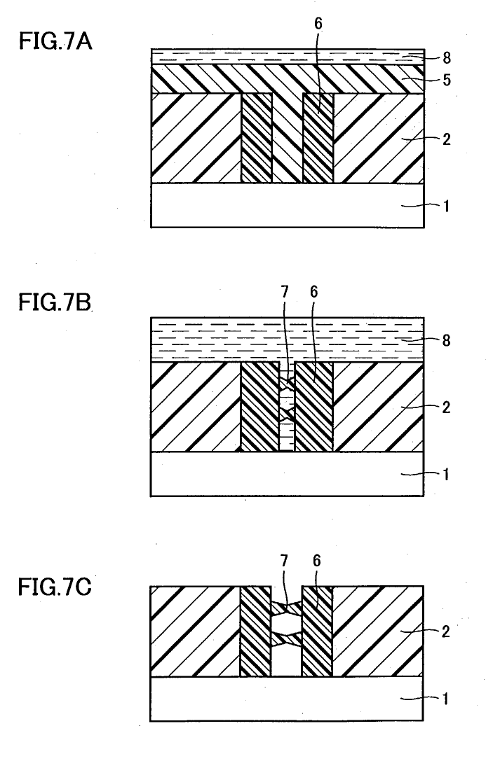

In the aforementioned resist pattern spacing reduction process, a residue may be generated as shown in FIGS. 7A-7C in the steps shown in FIGS. 6H-6J. When developer 8 is applied in the pure water development step as shown in FIG. 7A, non-cross-linked second resist 5 dissolves into developer 8, and second resist cross-linked layer 6 swells, which brings the sidewalls into contact with each other as shown in FIG. 7B. When the developer is washed and spin-dried, the swelling is eliminated and a residue 7 is likely to be generated, as shown in FIG. 7C.

The residue generated as such is removed without varying a dimension of a resist pattern spacing by irradiating the residue with an electron beam having an acceleration voltage lower than a prescribed value under a prescribed reduced pressure, as described above.

A manufacturing method of a semiconductor device according to the present invention is characterized in that, a residue generated between resist sidewalls is removed using the above-described resist pattern formation method. The formation method is applicable without special limitation to a manufacturing method of a semiconductor device having a process of resist pattern formation. By way of example, it is possible to perform an etching step using the aforementioned resist pattern as a mask, and remove the resist pattern by ashing to transfer the pattern. It is also possible to perform a doping step using the aforementioned resist pattern as a mask, and remove the resist pattern by ashing to dope a portion not covered with the resist pattern with a certain substance.

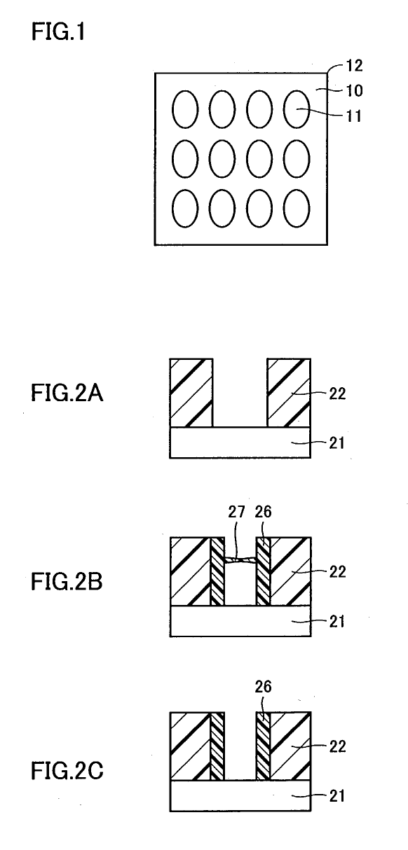

Embodiments of the present invention will now be described in detail with reference to FIGS. 1-5. First, examples of a resist pattern formation method according to the present invention are described.

### EXAMPLE 1

A chemically amplified excimer resist 22 (produced by TOKYO OHKA KOGYO CO., LTD.) was dropped on a silicon wafer 21 to form a film having a thickness of about 0.8 μm by spin coating. Pre-bake was performed for 90 seconds at 90° C. to dry solvent in the resist. Thereafter, an exposure step was performed with a hole pattern mask 12 having an elliptical light-transmitting portion 11 and a light-impermeable portion 10 as shown in FIG. 1, using a KrF excimer reduction projection exposure system. Post-exposure bake (PEB) for 90 seconds at 100° C. was then performed, followed by development using alkaline developer (NMD-W, produced by TOKYO OHKA KOGYO CO., LTD.) to obtain a first resist pattern as shown in FIG. 2A.

Spin coating was performed by dropping water-soluble upper layer agent (AZ R200, produced by Clariant Japan) as a second resist for a resist pattern spacing reduction process on the silicon wafer having the first resist pattern formed thereon. Pre-bake was then performed for 70 seconds at 85° C. to form a second resist film. Mixing-bake was performed for 90 seconds at 120° C. to enhance a cross-link reaction of the second resist. Development using pure water was performed to remove the non-crosslinked second resist, and then post-bake was performed for 90 seconds at 90° C. to form a second resist cross-linked layer 26 on the first resist pattern to form a second resist pattern.

A hole diameter (which means a minor axis hereafter) of the second resist pattern was 0.09 μm. An inspection for defects was performed on the wafer having the second resist pattern formed thereon using pattern defect inspection equipment (manufactured by KLA-Tencor). As a result, 100 defects were detected within an area of 25,000 mm² on the wafer. When the defective portion was observed with an electron microscope (manufactured by Hitachi, Ltd.), a residue 27 was found, which had a string-like form linking sidewalls of the resist, as shown in FIG. 2B. The defective portion was irradiated for 20 seconds with an electron beam having an acceleration voltage of 800V and a tube current of 5 μA, using the same device as the electron microscope used to observe the defective portion. As a result, the residue was removed as shown in FIG. 2C. The hole diameter of the pattern was 0.09 μm, showing no variation in the dimension of the resist pattern spacing.

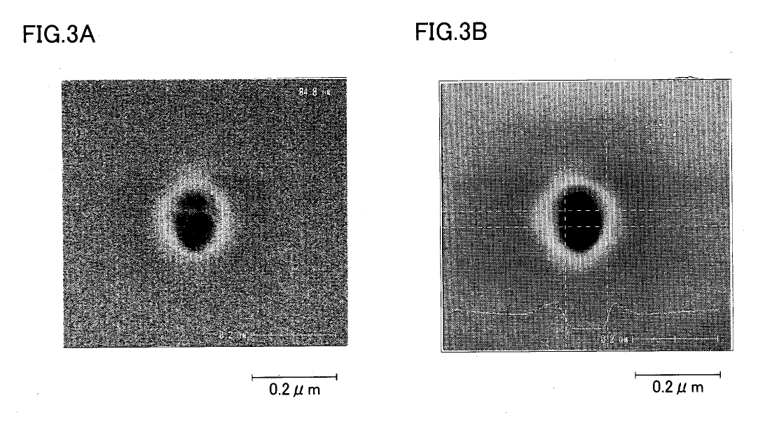

FIGS. 3A and 3B are microphotographs respectively showing a portion around the hole before and after the electron beam irradiation. It can be seen from FIGS. 3A and 3B that, the residue is removed without varying the dimension of the resist pattern spacing.

### EXAMPLE 2

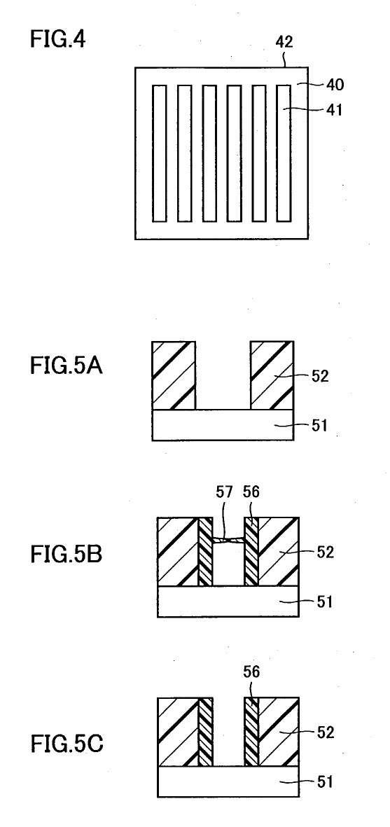

A chemically amplified excimer resist 52 (produced by TOKYO OHKA KOGYO CO., LTD.) was dropped on a silicon wafer 51 to form a film having a thickness of about 0.8 μm by spin coating. Pre-bake was performed for 90 seconds at 90° C. Thereafter, an exposure step was performed with a trench pattern mask 42 having a slit-like light-transmitting portion 41 and a light-impermeable portion 40 as shown in FIG. 4, using the KrF excimer reduction projection exposure system. Post-exposure bake (PEB) for 90 seconds at 100° C. was then performed, followed by development using alkaline developer (NMD-W, produced by TOKYO OHKA KOGYO CO., LTD.) to obtain a first resist pattern as shown in FIG. 5A.

Spin coating was performed by dropping water-soluble upper layer agent (AZ R200, produced by Clariant Japan) for the resist pattern spacing reduction process on the silicon wafer having the first resist pattern formed thereon. Pre-bake was then performed for 70 seconds at 85° C. to form a second resist film. Mixing-bake was performed for 90 seconds at 120° C. to enhance a cross-link reaction of the second resist. Development using pure water was performed to remove the non-cross-linked second resist, and then post-bake was performed for 90 seconds at 90° C. to form a second resist cross-linked layer 56 on the first resist pattern to form a second resist pattern.

A trench width of the second resist pattern was 0.09 μm. An inspection for defects was performed on the wafer having the second resist pattern formed thereon using pattern defect inspection equipment (manufactured by KLA-Tencor). As a result, 100 defects were detected within an area of 25,000 mm² on the wafer. When the defective portion was observed with an electron microscope (manufactured by Hitachi, Ltd.), a residue 57 was found, which had a string-like form linking sidewalls of the resist, as shown in FIG. 5B. The defective portion was irradiated for 20 seconds with an electron beam having an acceleration voltage of 800V and a tube current of 5 μA, using the same device as the electron microscope used to observe the defective portion. As a result, the residue was removed as shown in FIG. 5C. The trench width of the pattern was 0.09 μm, showing no variation in the dimension of the resist pattern spacing.

### EXAMPLE 3

First and second resist patterns were formed as described in the first example. A hole diameter of the second resist pattern was 0.09 μm. An inspection for defects was performed on the wafer having the second resist pattern formed thereon using pattern defect inspection equipment (manufactured by KLA-Tencor). As a result, 100 defects were detected within an area of 25,000 mm² on the wafer. When the defective portion was observed with an electron microscope (manufactured by Hitachi, Ltd.), a residue 27 was found, which had a string-like form linking sidewalls of the resist, as shown in FIG. 2B. The defective portion was irradiated for 20 seconds with an electron beam having an acceleration voltage of 300V and a tube current of 5 μA, using the same device as the electron microscope used to observe the defective portion. As a result, the residue was removed as shown in FIG. 2C. The hole diameter of the pattern was 0.09 μm, showing no variation in the dimension of the resist pattern spacing.

### EXAMPLE 4

First and second resist patterns were formed as described in the second example. A trench width of the second-resist pattern was 0.09 μm. An inspection for defects was performed on the wafer having the second resist pattern formed thereon using pattern defect inspection equipment (manufactured by KLA-Tencor). As a result, 100 defects were detected within an area of 25,000 mm² on the wafer. When the defective portion was observed with an electron microscope (manufactured by Hitachi, Ltd.), a residue 57 was found, which had a string-like form linking sidewalls of the resist, as shown in FIG. 5B. The defective portion was irradiated for 20 seconds with an electron beam having an acceleration voltage of 300V and a tube current of 5 μA, using the same device as the electron microscope used to observe the defective portion. As a result, the residue was removed as shown in FIG. 5C. The trench width of the pattern was 0.09 μm, showing no variation in the dimension of the resist pattern spacing.

### COMPARATIVE EXAMPLE 1

First and second resist patterns were formed as described in the first example. A hole diameter of the second resist pattern was 0.09 μm. An inspection for defects was performed on the wafer having the second resist pattern formed thereon using pattern defect inspection equipment (manufactured by KLA-Tencor). As a result, 100 defects were detected within an area of 25,000 mm² on the wafer. When the defective portion was observed with an electron microscope (manufactured by Hitachi, Ltd.), a residue 27 was found, which had a string-like form linking sidewalls of the resist, as shown in FIG. 2B. The defective portion was irradiated for 20 seconds with an electron beam having an acceleration voltage of 1500V and a tube current of 5 μA, using the same device as the electron microscope used to observe the defective portion. As a result, though the residue was removed as shown in FIG. 2C, the hole diameter of the pattern was 0.10 μm, showing a variation in the dimension of the resist pattern spacing.

### COMPARATIVE EXAMPLE 2

First and second resist patterns were formed as described in the second example. A trench width of the second resist pattern was 0.09 μm. An inspection for defects was performed on the wafer having the second resist pattern formed thereon using pattern defect inspection equipment (manufactured by KLA-Tencor). As a result, 100 defects were detected within an area of 25,000 mm² on the wafer. When the defective portion was observed with an electron microscope (manufactured by Hitachi, Ltd.), a residue 57 was found, which had a string-like form linking sidewalls of the resist, as shown in FIG. 5B. The defective portion was irradiated for 20 seconds with an electron beam having an acceleration voltage of 1500V and a tube current of 5 μA, using the same device as the electron microscope used to observe the defective portion. As a result, though the residue was removed as shown in FIG. 5C, the trench width of the pattern was 0.10 μm, showing a variation in the dimension of the resist pattern spacing.

Examples of a manufacturing method of a semiconductor device according to the present invention will now be described, which method uses a resist pattern formation method which is characterized in that, a string-like residue is removed without varying a dimension of a resist pattern spacing.

First and second resist patterns were formed as described in the first example using a silicon wafer having a silicon oxide film as a top layer. A residue was removed while maintaining a hole diameter of the second resist pattern at 0.09 μm by irradiation for 20 seconds with an electron beam having an acceleration voltage of 300V and a tube current of 5 μA. The hole pattern having a 0.09 μm diameter is transferred to the silicon oxide film by dry-etching the silicon oxide film using the second resist pattern as a mask after the residue has been removed, and then ashing the whole resist pattern.

First and second resist patterns were formed as described in the second example using a silicon wafer having a polysilicon film as a top layer. A residue was removed while maintaining a trench width of the second resist pattern at 0.09 μm by irradiation for 20 seconds with an electron beam having an acceleration voltage of 300V and a tube current of 5 μA. The trench pattern having a 0.09 μm width is transferred to the polysilicon film by dry-etching the polysilicon film using the second resist pattern as a mask after the residue has been removed, and then ashing the whole resist pattern.

First and second resist patterns were formed as described in the first example using a silicon wafer having a silicon oxide film as a top layer. A residue was removed while maintaining a hole diameter of the second resist pattern at 0.09 μm by irradiation for 20 seconds with an electron beam having an acceleration voltage of 300V and a tube current of 5 μA. Boron could be implanted only to the hole portion by implanting boron using the second resist pattern as a mask after the residue has been removed, and then ashing the whole resist pattern.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A resist pattern formation method, wherein
after a resist pattern is formed on a wafer, a residue generated between resist sidewalls forming the resist pattern is removed without varying a dimension of a resist pattern spacing by irradiating the residue with an electron beam under a reduced pressure.

2. A resist pattern formation method, wherein
after a resist pattern is formed on a wafer, a residue generated between resist sidewalls forming the resist pattern is detected using pattern defect inspection equipment, and is removed without varying a dimension of a resist pattern spacing by irradiating a detected residue site with an electron beam under a reduced pressure.
